(19) United States
(12) Patent Application Publication
(10) Pub. No.: US 2025/0301759 A1
(43) Pub. Date: Sep. 25, 2025

(54) SEMICONDUCTOR DEVICE AND METHOD OF FORMING THE SAME

(71) Applicant: HON HAI PRECISION INDUSTRY CO., LTD., New Taipei City (TW)

(72) Inventor: Yun-Hung SHEN, Hsinchu City (TW)

(21) Appl. No.: 18/664,323

(22) Filed: May 15, 2024

(30) Foreign Application Priority Data
Mar. 21, 2024 (TW) 113110617

(51) Int. Cl. H01L 29/51; H01L 21/28; H01L 21/311; H01L 29/49

(52) U.S. Cl. CPC H10D 64/693; H01L 21/28194; H01L 21/31138; H10D 64/661

(57) ABSTRACT

A method of forming semiconductor device includes forming a gate structure on a substrate; sequentially depositing a nitride layer and a carbonitride layer covering the gate structure and the substrate, in which the carbonitride layer is deposited by an atomic layer deposition process; depositing an interlayer dielectric layer on the carbonitride layer; performing a planarization process to expose a top surface of the gate structure; forming a protective layer on the top surface of the gate structure; forming a contact hole in the interlayer dielectric layer, the carbonitride layer, and the nitride layer; and filling a metal layer in the contact hole to form a contact plug. A semiconductor device is also disclosed.

### RELATED APPLICATIONS

This application claims priority to Taiwanese Application Serial Number 113110617, filed Mar. 21, 2024, which is herein incorporated by reference.

### FIELD OF INVENTION

The present disclosure relates to a semiconductor device and method of forming the same.

### DESCRIPTION OF RELATED ART

With the development of semiconductor technique, requirements for faster processing systems and better performances are also increased. In order to satisfy these requirements, critical dimensions of the CMOS devices are reduced to increase the density of the CMOS devices. However, during the over etch process for forming contact holes, poor fabrication control may lead to too many metal silicide loss under the contact holes thereby causing junction leakage and gate induced drain leakage.

### SUMMARY

An aspect of the disclosure provides a method of forming semiconductor device. The method includes forming a gate structure on a substrate; sequentially depositing a nitride layer and a carbonitride layer covering the gate structure and the substrate, in which the carbonitride layer is deposited by an atomic layer deposition process; depositing an interlayer dielectric layer on the carbonitride layer; performing a planarization process to expose a top surface of the gate structure; forming a protective layer on the top surface of the gate structure; forming a contact hole in the interlayer dielectric layer, the carbonitride layer, and the nitride layer; and filling a metal layer in the contact hole to form a contact plug.

An aspect of the disclosure provides a semiconductor device. The semiconductor device includes a substrate, a gate structure disposed on the substrate, a spacer disposed on a sidewall of the gate structure, a nitride layer covering the spacer and the substrate, a carbonitride layer covering and contacting the nitride layer, a protective layer covering and contacting a top surface of the gate structure, an interlayer dielectric layer disposed on the protective layer and the carbonitride layer, and a contact plug disposed in the interlayer dielectric layer, the carbonitride layer, and the nitride layer.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 to FIG. 7 are cross-sectional views of different stages of a method of forming a semiconductor device according to some embodiments of the disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

During the over etch process for forming contact holes, poor fabrication control may lead to too many metal silicide loss under the contact holes thereby causing junction leakage and gate induced drain leakage. Therefore, the present disclosure provides a method of forming a semiconductor device. A gate structure is formed on a substrate. A nitride layer, a carbonitride layer, and an interlayer dielectric layer are sequentially deposited to cover the gate structure and the substrate, in which the carbonitride layer is formed by an atomic layer deposition process. A planarization process is performed to expose the gate structure. A protective layer is formed to cover the gate structure and the top surface of the nitride layer. A contact hole is formed in the interlayer dielectric layer, the carbonitride layer, and the nitride layer. A contact plug is formed by filling the contact hole with a metal layer. The carbonitride layer and the nitride layer together serve as a contact etch stop layer (CESL) to prevent the metal silicide layer under the contact hole from being damaged during the over etch process for forming the contact hole. Details of the semiconductor device and the method of forming the same are discussed with the following drawings.

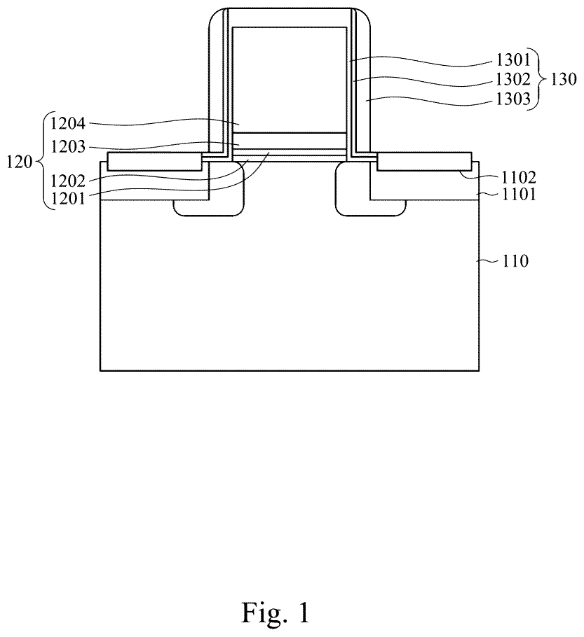

Please refer to FIG. 1 to FIG. 7. FIG. 1 to FIG. 7 are cross-sectional views of different stages of a method of forming a semiconductor device according to some embodiments of the disclosure. The below illustrations include exemplary operations, but the operations are not necessarily performed in the order shown. Operations may be added, replaced, changed order, and/or eliminated as appropriate, in accordance with the spirit and scope of various embodiments of the present disclosure.

Reference is made to FIG. 1. A gate structure 120 is formed on a substrate 110. In some embodiments, the gate structure 120 from bottom to top sequentially includes a gate dielectric layer 1201, a high-k dielectric layer 1202, a cap layer 1203, and a gate electrode layer 1204. The gate structure 120 can be formed by a CVD deposition, A PVD deposition, an electron beam vapor deposition and/or any suitable deposition processes. In some embodiments, the gate dielectric layer 1201 may include oxide such as silicon oxide, nitride such as silicon nitride, oxynitride such as silicon oxynitride, the combinations thereof or the like. In some embodiments, the high-k dielectric layer 1202 may include high-k dielectric material. For example, the material of the high-k dielectric layer 1202 includes metal oxide such as HfO₂, Y₂O₃, Y₂TiO₅, Yb₂O₃, ZrO₂, TiO₂, Al₂O₃, Y₂O₃, Ta₂O₅, the combinations thereof or the like. In some embodiments, the cap layer 1203 may include metal nitride such as titanium nitride, tantalum nitride, the combination thereof or the like. In some embodiments, the gate electrode layer 1204 may include conductive material such as tantalum, tungsten, tantalum nitride, titanium nitride, or combinations thereof. In some embodiments, the gate electrode layer 1204 may include semiconductor material such as poly silicon or the like.

Still referring to FIG. 1, in some embodiments, the method further includes forming source/drain (S/D) regions 1101 in the substrate 110, and forming a metal silicide layer 1102 on the S/D regions 1101 after the gate structure 120 is formed on the substrate 110, in which portions of the metal silicide layer 1102 is protruded from the surface of the substrate 110. The S/D regions 1101 can be formed by performing an ion implantation process, and the metal silicide layer 1102 can be formed by a metal silicide process. In some embodiments, the metal silicide layer 1102 may include titanium silicide, cobalt silicide, nickel silicide, platinum silicide, or combinations thereof.

Still referring to FIG. 1, in some embodiments, the method further includes forming spacers 130 at the sidewalls of the gate structure 120 prior to forming the S/D regions 1101, and the S/D regions 1101 are formed including using the spacers 130 as a mask during the ion implantation process. The spacers 130 can be formed by performing a suitable deposition process followed by an anisotropic dry etching process. The spacers 130 include insulating material. In some embodiments, the spacers 130 includes a first silicon nitride layer 1301, a second silicon nitride layer 1303, and a silicon oxide layer 1302 between the first silicon nitride layer 1301 and the second silicon nitride layer 1303.

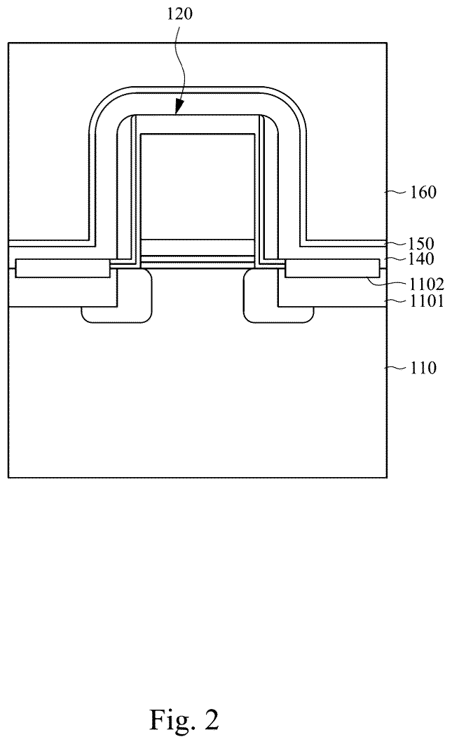

Reference is made to FIG. 2. A nitride layer 140, a carbonitride layer 150, and an interlayer dielectric layer 160 are sequentially deposited to cover the gate structure 120 and the substrate 110. The nitride layer 140 and the carbonitride layer 150 together serve as an contact etch stop layer to prevent the metal silicide layer 1102 under the contact hole from being damaged during the over etch process for forming the contact hole. The carbonitride layer 150 includes carbon-nitride double bond (C═N), so that the carbonitride layer 150 can provide better anti-etching ability as described in the following description. Therefore, the carbonitride layer 150 can provide sufficient anti-etching ability even with a thinner thickness. The interlayer dielectric layer 160 includes silicon oxide, silicon nitride, silicon oxynitride, tetraethyl orthosilicate (TEOS), low-k dielectric material, or combinations thereof. In some embodiments, the interlayer dielectric layer 160 includes TEOS. The nitride layer 140 and the interlayer dielectric layer 160 can be formed by an ALD process, a CVD deposition, A PVD deposition, an electron beam vapor deposition and/or any suitable deposition processes. In some embodiments, the carbonitride layer 150 is formed by performing an ALD process. In some embodiments, the temperature of the ALD process is in a range from 300° C. to 400° C., such as 300° C., 320° C., 340° C., 360° C., 380° C. or 400° C. In some embodiments, a thickness of the carbonitride layer 150 is in a range from 15 Å to 50 Å, such as 15 Å, 20 Å, 30 Å, 40 Å, or 50 Å. When the thickness of the carbonitride layer 150 is in above range, the thickness of the carbonitride layer 150 is sufficient to be served as the etch stop layer. In some embodiments, a thickness of the nitride layer 140 is in a range from 150 Å to 250 Å, such as 150 Å, 175 Å, 200 Å, 225 Å, or 250 Å. When the thickness of the nitride layer 140 is in above range, the nitride layer 140 can generate stress to adjust the channel stress thereby improving carrier mobility and enhancing transistor performance.

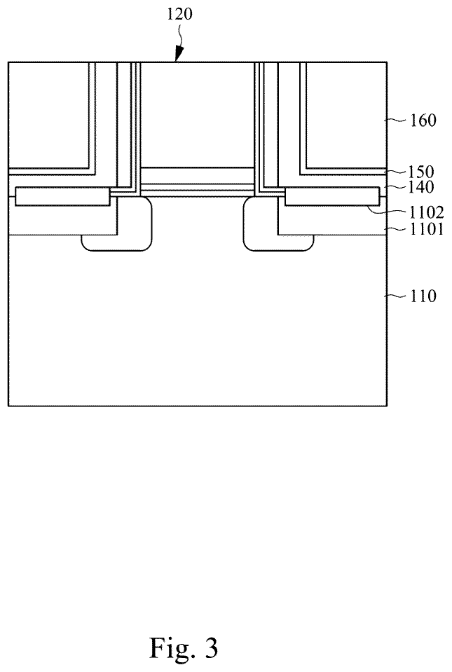

Reference is made to FIG. 3. A planarization process is performed to expose the gate structure 120. The materials above the gate structure 120 can be removed by a chemical-mechanical planarization process to expose the gate structure 120.

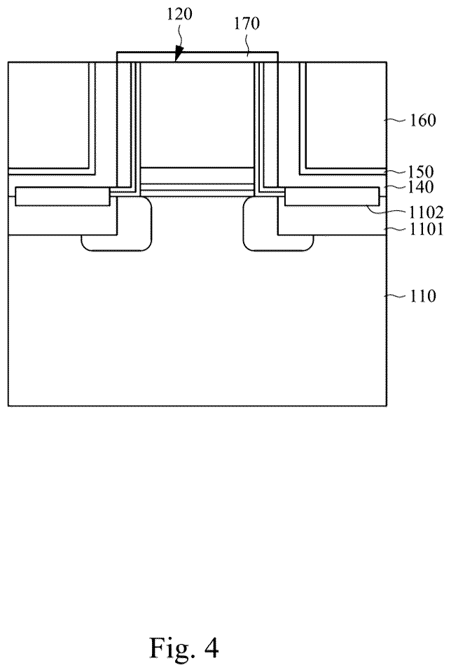

Reference is made to FIG. 4. A protective layer 170 is formed to cover the top surface of the gate structure 120. In some embodiments, the protective layer 170 includes carbonitride. In some embodiments, the protective layer 170 is formed by performing an ALD process. In some embodiments, a thickness of the protective layer 170 is in a range from 35 Å to 70 Å, such as 35 Å, 40 Å, 50 Å, 60 Å, or 70 Å. When the thickness of the protective layer 170 is in above range, the protective layer 170 can protect the gate structure 120 to prevent the gate structure from being damaged or loss during the following processes for forming gate contacts.

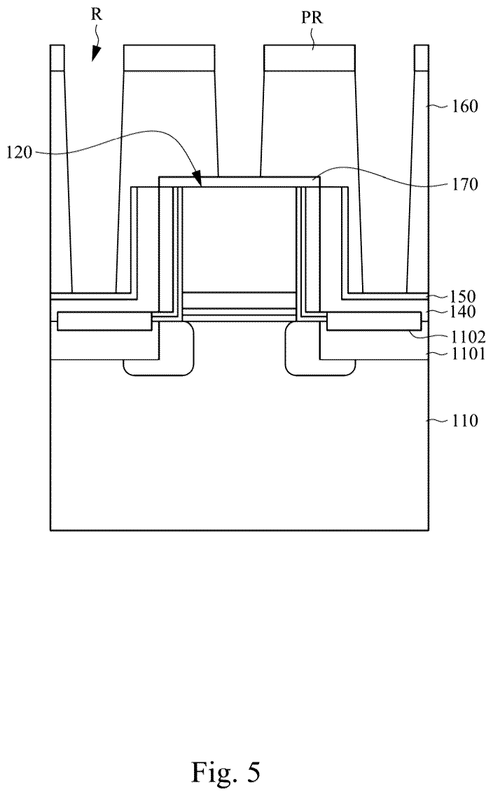

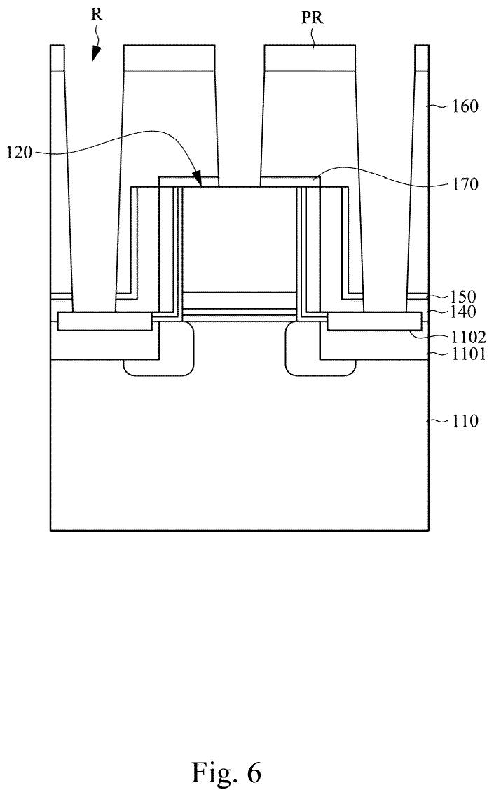

Reference is made to FIG. 5 and FIG. 6. Contact holes R are formed in the interlayer dielectric layer 160, the carbonitride layer 150, and the nitride layer 140. The contact holes R are formed by a wet etching process and/or a dry etching process including using the photoresist layer PR having openings as a mask. In some embodiments, as shown in FIG. 5, forming the contact holes R in the interlayer dielectric layer 160, the carbonitride layer 150, and the nitride layer 140 includes performing a first etching process to remove portions of the interlayer dielectric layer 160. Then, as shown in FIG. 6, a second etching process is performed to remove portions of the protective layer 170, the carbonitride layer 150, and the nitride layer 140. The first etching process and the second etching process can respectively use different wet etching process and/or dry etching process. In some embodiments, the first etching process and the second etching process respectively are plasma etching processes. In some embodiments, the temperatures of the first etching process and the second etching process respectively are equal to or less than under 120° C.

Reference is made to FIG. 5. In some embodiments, an etching selectivity between the interlayer dielectric layer 160 and the carbonitride layer 150 of the first etching process is form 10 to 50 such as 10, 20, 30, 40, or 50. In some embodiments, the first etching process includes using fluorine-containing gas, oxygen, and argon. The fluorine-containing gas includes SF₆, CF₄, CHF₃, C₂F₆, C₃F₈, C₄F₆, C₄F₈, C₅F₈, or combinations thereof. The fluorine-containing gas, oxygen, and argon have poor etching ability to the nitride layer 140 and the carbonitride layer 150. Therefore, the first etching process selectively etches the interlayer dielectric layer 160 and does not damage the underlying nitride layer 140 and the carbonitride layer 150.

Reference is made to FIG. 6. In some embodiments, the second etching process includes using NF₃, fluorine-containing gas, oxygen, and argon. The fluorine-containing gas includes SF₆, CF₄, CHF₃, C₂F₆, C₃F₈, C₄F₆, C₄F₈, C₅F₈, or combinations thereof. Comparing to the fluorine-containing gas, oxygen, and argon, NF₃ has a better etching rate to carbon-nitride double bond, so that NF₃ is utilized in the second etching process to etch the nitride layer 140 and the carbonitride layer 150. Therefore, the metal silicide layer 1102 under the contact holes R would not be easily damaged by the first etching process and the second etching process for forming the contact holes R.

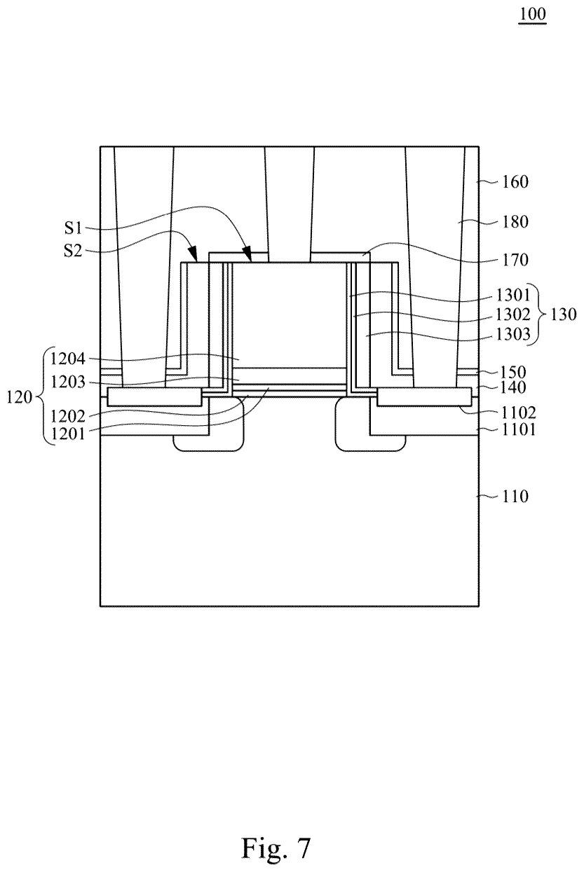

Reference is made to FIG. 7. A metal layer is filled in the contact holes R to form contact plugs 180. The metal layer may include conductive material such as tantalum, tungsten, tantalum nitride, titanium nitride, or combinations thereof. The metal layer can be deposited in the contact holes R by a CVD process, a PVD process or other suitable deposition process. The photoresist layer PR is further removed by such as an ashing process or an etching process.

The semiconductor device formed by above is also disclosed. Reference is made to FIG. 7 again. The semiconductor device 100 includes the substrate 110, the gate structure 120, the spacers 130, the nitride layer 140, the carbonitride layer 150, the interlayer dielectric layer 160, the protective layer 170, and contact plugs 180. The gate structure 120 is disposed on the substrate 110. The spacers 130 are disposed on sidewalls of the gate structure 120. The nitride layer 140 covers the spacers 130 and the substrate 110. The carbonitride layer 150 covers and contacts the nitride layer 140. The protective layer 170 covers and contacts the top surface S1 of the gate structure 120. The interlayer dielectric layer 160 is disposed on the protective layer 170 and the carbonitride layer 150. The contact plugs 180 are disposed in the interlayer dielectric layer 160, the carbonitride layer 150, and the nitride layer 140. In some embodiments, the material of the carbonitride layer 150 can be same as the material of the protective layer 170. In some embodiments, the thickness of the carbonitride layer 150 is in a range from 15 Å to 50 Å. In some embodiments, the thickness of the nitride layer 140 is in a range from 150 Å to 250 Å. In some embodiments, the thickness of the protective layer 170 is in a range from 35 Å to 70 Å. In some embodiments, the semiconductor device 100 further includes S/D regions 1101 and metal silicide layer 1102. The S/D regions 1101 are disposed in the substrate 110. The metal silicide layer 1102 is disposed on the S/D regions 1101, and a portion of the metal silicide layer 1102 is protruded from the surface of the substrate 110. In some embodiments, the bottom of the contact plugs 180 contacts the metal silicide layer 1102. In some embodiments, the protective layer 170 covers and contacts the top surface of the spacers 130. In some embodiments, the top surface S1 of the gate structure 120 and the top surface S2 of the nitride layer 140 and the carbonitride layer 150 on the sidewall of the gate structure 120 are coplanar. In some embodiments, the top surface S2 of the nitride layer 140 and the carbonitride layer 150 is not covered by the protective layer 170.

According to embodiments of the disclosure, a method of forming a semiconductor device is provided. A gate structure is formed on a substrate. A nitride layer, a carbonitride layer, and an interlayer dielectric layer are sequentially deposited to cover the gate structure and the substrate, in which the carbonitride layer is formed by an atomic layer deposition process. A planarization process is performed to expose the gate structure. A protective layer is formed to cover the gate structure and the top surface of the nitride layer. A contact hole is formed in the interlayer dielectric layer, the carbonitride layer, and the nitride layer. A contact plug is formed by filling the contact hole with a metal layer. The carbonitride layer and the nitride layer together serve as a contact etch stop layer to prevent the metal silicide layer under the contact hole from being damaged during the over etch process for forming the contact hole due to poor fabrication control.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A method of forming semiconductor device comprising;
forming a gate structure on a substrate;
sequentially depositing a nitride layer and a carbonitride layer covering the gate structure and the substrate, wherein the carbonitride layer is deposited by an atomic layer deposition process;
depositing an interlayer dielectric layer on the carbonitride layer;
performing a planarization process to expose a top surface of the gate structure;
forming a protective layer on the top surface of the gate structure;
forming a contact hole in the interlayer dielectric layer, the carbonitride layer, and the nitride layer; and
filling a metal layer in the contact hole to form a contact plug.

2. The method of claim 1, wherein forming a contact hole in the interlayer dielectric layer, the carbonitride layer, and the nitride layer comprises:
performing a first etching process to remove a portion of the interlayer dielectric layer; and
performing a second etching process to remove portions of the carbonitride layer and the nitride layer.

3. The method of claim 2, wherein the first etching process comprises using fluorine-containing gas, oxygen, and argon.

4. The method of claim 3, wherein fluorine-containing gas comprises F₆, CF₄, CHF₃, C₂F₆, C₃F₈, C₄F₆, C₄F₈, C₅F₈, or combinations thereof.

5. The method of claim 2, wherein the second etching process comprises using NF₃, fluorine-containing gas, oxygen, and argon.

6. The method of claim 5, wherein fluorine-containing gas comprises F₆, CF₄, CHF₃, C₂F₆, C₃F₈, C₄F₆, C₄F₈, C₅F₈, or combinations thereof.

7. The method of claim 2, wherein an etching selectivity between the interlayer dielectric layer and the carbonitride layer of the first etching process is form 10 to 50.

8. The method of claim 1, further comprising:
forming a S/D region in the substrate after the gate structure is formed on the substrate; and
forming a metal silicide layer on the S/D region, wherein a portion of the metal silicide layer is protruded from a surface of the substrate.

9. The method of claim 8, wherein a bottom of the contact plug contacts the metal silicide layer.

10. The method of claim 1, wherein after performing the planarization process, the top surface of the gate structure and a top surface of the nitride layer and the carbonitride layer on a sidewall of the gate structure are coplanar.

11. The method of claim 10, wherein the top surface of the nitride layer and the carbonitride layer is not covered by the protective layer.

12. The method of claim 1, wherein a temperature of the atomic layer deposition process is in a range from 300° C. to 400° C.

13. A semiconductor device comprising:
a substrate;
a gate structure disposed on the substrate;
a spacer disposed on a sidewall of the gate structure;
a nitride layer covering the spacer and the substrate;
a carbonitride layer covering and contacting the nitride layer;
a protective layer covering and contacting a top surface of the gate structure;
an interlayer dielectric layer disposed on the protective layer and the carbonitride layer; and
a contact plug disposed in the interlayer dielectric layer, the carbonitride layer, and the nitride layer.

14. The semiconductor device of claim 13, wherein a material of the carbonitride layer is same as a material of the protective layer.

15. The semiconductor device of claim 13, wherein the protective layer covers and contacts a top surface of the spacer.

16. The semiconductor device of claim 13, further comprising:
a S/D region in the substrate; and
a metal silicide layer on the S/D region, wherein a portion of the metal silicide layer is protruded from a surface of the substrate.

17. The semiconductor device of claim 16, wherein a bottom of the contact plug contacts the metal silicide layer.

18. The semiconductor device of claim 13, wherein the top surface of the gate structure and a top surface of the nitride layer and the carbonitride layer on the sidewall of the gate structure are coplanar.

19. The semiconductor device of claim 18, wherein the top surface of the nitride layer and the carbonitride layer is not covered by the protective layer.

20. The semiconductor device of claim 13, wherein a thickness of the carbonitride layer is thinner than a thickness of the nitride layer.
